(19) United States
(12) Patent Application Publication
(10) Pub. No.: US 2024/0392193 A1
(43) Pub. Date: Nov. 28, 2024

(54) ETCHING COMPOSITION FOR SILICON NITRIDE LAYER AND METHOD FOR ETCHING SILICON NITRIDE LAYER USING THE SAME

(71) Applicant: SAMSUNG SDI CO., LTD., Yongin-si, Gyeonggi-do (KR)

(72) Inventor: Gyeonghun PARK, Suwon-si (KR)

(21) Appl. No.: 18/657,598

(22) Filed: May 7, 2024

(30) Foreign Application Priority Data
May 25, 2023 (KR) 10-2023-0067887

(51) Int. Cl. C09K 13/06; C04B 35/584; C04B 41/53; C04B 41/91

(52) U.S. Cl. CPC C09K 13/06; C04B 35/584; C04B 41/5353; C04B 41/91

(57) ABSTRACT

An etching composition for a silicon nitride layer includes phosphoric acid, a compound represented by Chemical Formula 1, a compound represented by Chemical Formula 2, and water. In addition, a method for etching a silicon nitride layer includes contacting a surface of a silicon nitride layer with the etching composition for a silicon nitride layer.

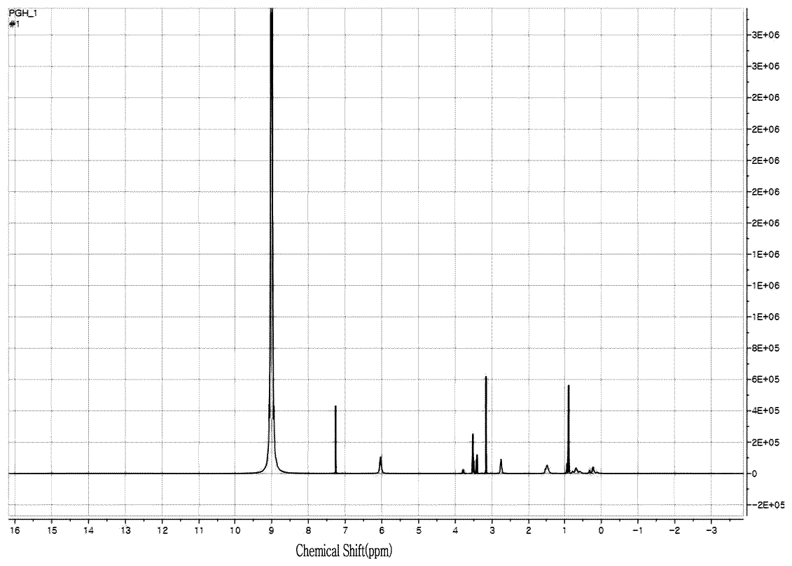

(R¹)ₐ(R²)_{b}(CH₃)Si—(OR³)_{(3-a-b)} Chemical Formula 1

(R⁵)_{c}(R⁶)_{d}(R⁷)Si—(OR⁸)_{(3-c-d)} Chemical Formula 2

### CROSS-REFERENCE TO RELATED APPLICATION

The present application claims priority to and the benefit of Korean Patent Application No. 10-2023-0067887, filed on May 25, 2023, in the Korean Intellectual Property Office, the entire content of which is incorporated herein by reference.

### BACKGROUND

### 1. Field

One or more embodiments of the present disclosure relate to an etching composition for a silicon nitride layer and a method for etching a silicon nitride layer utilizing the etching composition.

### 2. Description of the Related Art

Various semiconductor manufacturing processes require a selective etching process for a silicon nitride layer. Recently, for the V-NAND manufacturing process, the development of a process for selectively removing only a silicon nitride layer from a structure in which silicon nitride layers and silicon oxide layers are alternately stacked and the development of an etching composition solution to implement the process are actively being pursued.

### SUMMARY

One or more aspects of embodiments of the present disclosure are directed toward an etching composition for a silicon nitride layer that may reduce bubbles generated by physical friction.

One or more aspects of embodiments of the present disclosure are directed toward an etching method utilizing the etching composition for a silicon nitride layer.

Additional aspects will be set forth in part in the description which follows and, in part, will be apparent from the description, or may be learned by practice of the presented embodiments of the disclosure.

According to one or more embodiments of the present disclosure, an etching composition for a silicon nitride layer includes phosphoric acid, a compound represented by Chemical Formula 1, a compound represented by Chemical Formula 2, and water, wherein the etching composition includes about 11 wt % to about 16 wt % of water based on a total weight of the etching composition, and in an ¹H-NMR (proton nuclear magnetic resonance) spectrum, a ratio of an area of a peak derived from Si—OR^{a} (wherein R^{a} is a substituted or unsubstituted alkyl group) to an area of a peak derived from Si—CH₃ is about 2 to about 16:

(R¹)ₐ(R²)_{b}(CH₃)Si—(OR³)_{(3-a-b)}, Chemical Formula 1
in Chemical Formula 1,
R¹ and R² may each independently be hydrogen, deuterium, or a substituted or unsubstituted C1 to C10 alkyl group,
R³ may each independently be a substituted or unsubstituted C1 to C10 alkyl group,
a and b may each independently be an integer from 0 to 2, and 0≤a+b≤2;

(R⁵)_{c}(R⁶)_{d}(R⁷)Si—(OR⁸)_{(3-c-d)}, Chemical Formula 2
in Chemical Formula 2,
R⁵ and R⁶ may each independently be hydrogen, deuterium, a C1 to C10 alkyl group, a group in which at least one hydrogen of C1 to C10 alkyl group is substituted with —NR^{c}R^{d}, or a group in which at least one —CH₂— of a C2 to C10 alkyl group is replaced by —NR^{e}—,
R⁷ may be a substituted or unsubstituted C1 to C10 alkyl group, wherein (i) one or more hydrogens of the alkyl group are substituted with —NR^{f}R^{g}, or (ii) the alkyl group is a C2 to C10 alkyl group in which at least one —CH₂— is a group replaced by —NR^{h}—,
R^{c} to R^{h} may each independently be hydrogen, a substituted or unsubstituted C1 to C5 alkyl group, a substituted or unsubstituted C3 to C10 cycloalkyl group, a substituted or unsubstituted C6 to C10 aryl group, or a (e.g., any suitable) combination thereof,
R⁸ may be a substituted or unsubstituted C1 to C10 alkyl group,
c and d may each independently be one of integers from 0 to 2, and 0≤c+d≤2.

In one or more embodiments, in Chemical Formula 1, R¹ to R³ may each independently be a substituted or unsubstituted C1 to C5 alkyl group.

In one or more embodiments, in Chemical Formula 1, R³ may be a methyl group, an ethyl group, or a propyl group.

In one or more embodiments, a+b in Chemical Formula 1 may be 0.

In one or more embodiments, in Chemical Formula 2, R⁵ to R⁷ may each independently be a substituted or unsubstituted C1 to C10 alkyl group, wherein (i) one or more hydrogens of the alkyl group are substituted with —NR^{f}R^{g}, or (ii) the alkyl group is a C2 to C10 alkyl group in which at least one —CH₂— is a group replaced by —NR^{h}—.

In one or more embodiments, R^{c} to R^{h} may each independently be hydrogen, a substituted or unsubstituted C1 to C5 alkyl group, or a (e.g., any suitable) combination thereof.
in one or more embodiments, c+d in Chemical Formula 2 is 0.

In one or more embodiments, a water content (e.g., amount) is about 12 wt % to about 15 wt % based on the total weight of the etching composition.

In one or more embodiments, a ratio of an area of a peak derived from Si—OR^{a} (wherein R^{a} is a substituted or unsubstituted alkyl group) to an area of a peak derived from Si—CH₃ is about 2 to about 10.

In one or more embodiments, a content (e.g., amount) of the compound represented by Chemical Formula 1 is about 0.3 wt % to about 10 wt % based on the total weight of the etching composition.

In one or more embodiments, a content (e.g., amount) of the compound represented by Chemical Formula 2 is about 0.5 wt % to about 30 wt % based on the total weight of the etching composition.

According to one or more embodiments, a method for etching a silicon nitride layer includes contacting a surface of a silicon nitride layer with the etching composition for a silicon nitride layer.

The etching composition for a silicon nitride layer according to one or more embodiments may reduce bubbles generated by physical friction and shorten a time (e.g., a duration) taken to heat the etching composition to an etching temperature.

### BRIEF DESCRIPTION OF DRAWING

Features will become apparent to those of skill in the art by describing in detail exemplary embodiments with reference to the attached drawing in which:

The drawing is a 1H-NMR spectrum of the etching composition for silicon nitride layer according to Example 1.

### DETAILED DESCRIPTION

Example embodiments of the present disclosure will hereinafter be described in more detail, and may be readily performed with reference to the described embodiments by a person skilled in the art. However, the present disclosure may be embodied in many different forms and is not construed as limited to the example embodiments set forth herein.

As utilized herein, if (e.g., when) a definition is not otherwise provided, ‘substituted’ may refer to replacement of a hydrogen of a compound by a substituent of (e.g., selected from among) deuterium, a halogen (fluorine (F), bromine (Br), chlorine (Cl), or iodine (I)), a hydroxy group, a nitro group, a cyano group, an amino group, an azido group, an amidino group, a hydrazino group, a hydrazono group, a carbonyl group, a carbamoyl group, a thiol group, an ester group, a carboxyl group or a salt thereof, a sulfonic acid group or a salt thereof, a phosphoric acid or a salt thereof, a C1 to C30 alkyl group, a C2 to C30 alkenyl group, a C2 to C30 alkynyl group, a C6 to C30 aryl group, a C7 to C30 arylalkyl group, a C1 to C30 alkoxy group, a C1 to C20 heteroalkyl group, a C3 to C20 heteroarylalkyl group, a C3 to C30 cycloalkyl group, a C3 to C15 cycloalkenyl group, a C6 to C15 cycloalkynyl group, a C2 to C30 heterocyclic group, and/or a (e.g., any suitable) combination thereof.

In one or more embodiments, adjacent two substituents selected from among the substituted halogen (F, Br, Cl, or I), the hydroxy group, the nitro group, the cyano group, the amino group, the azido group, the amidino group, the hydrazino group, the hydrazono group, the carbonyl group, the carbamoyl group, the thiol group, the ester group, the carboxyl group or the salt thereof, the sulfonic acid group or the salt thereof, the phosphoric acid or the salt thereof, the C1 to C30 alkyl group, the C2 to C30 alkenyl group, the C2 to C30 alkynyl group, the C6 to C30 aryl group, the C7 to C30 arylalkyl group, the C1 to C30 alkoxy group, the C1 to C20 heteroalkyl group, the C3 to C20 heteroarylalkyl group, the C3 to C30 cycloalkyl group, the C3 to C15 cycloalkenyl group, the C6 to C15 cycloalkynyl group, and the C2 to C30 heterocyclic group may be fused (e.g., bonded to each other) to form (or provide) a ring.

As utilized herein, “aryl group” may refer to a group including at least one hydrocarbon aromatic moiety, and may include hydrocarbon aromatic moieties linked by a single bond and hydrocarbon aromatic moieties fused directly or indirectly to provide a non-aromatic fused ring. The aryl group may include a monocyclic, polycyclic, or fused polycyclic (i.e., rings sharing adjacent pairs of carbon atoms) functional group.

For example, the substituted or unsubstituted aryl group may be a substituted or unsubstituted phenyl group, a substituted or unsubstituted naphthyl group, a substituted or unsubstituted anthracenyl group, a substituted or unsubstituted phenanthryl group, a substituted or unsubstituted naphthacenyl group, a substituted or unsubstituted pyrenyl group, a substituted or unsubstituted biphenyl group, a substituted or unsubstituted terphenyl group, a substituted or unsubstituted quaterphenyl group, a substituted or unsubstituted chrysenyl group, a substituted or unsubstituted triphenylenyl group, a substituted or unsubstituted perylenyl group, a combination thereof, or a combined fused ring of two or more of the foregoing groups, but embodiments of the present disclosure are not limited thereto.

As utilized herein, if (e.g., when) a specific definition is not otherwise provided, the term “combination” refers to mixing or copolymerization.

In the related art, an aqueous phosphoric acid solution heated to a high temperature has been utilized as an etching solution to remove a silicon nitride layer pattern formed on a substrate during a semiconductor manufacturing process. However, if this etchant is utilized as it is, not only the silicon nitride layer but also the silicon oxide layer is etched, which has the problem and/or issue of failing to meet a silicon nitride layer/silicon oxide layer selectivity ratio desired or required in the process. In order to solve the above problems and issues, research is being actively conducted on one or more suitable additives to be utilized with phosphoric acid.

To increase the etch selectivity of the silicon nitride layer to the silicon oxide layer, a silane-based compound may be utilized along with a phosphoric acid solution. If a silane-based compound is included in the etching composition for a silicon nitride layer, the etch selectivity may be improved. However, if the content (e.g., amount) of the silane-based compound increases, bubbles may be generated due to physical friction, which may be disadvantageous in terms of etching process efficiency. Accordingly, it is desired or required to include a silane-based compound in the etching composition for a silicon nitride layer to improve the etch selectivity while suppressing or reducing the generation of bubbles or quickly removing the generated bubbles.

According to one or more embodiments of the present disclosure, an etching composition for a silicon nitride layer may include phosphoric acid, a compound represented by Chemical Formula 1, a compound represented by Chemical Formula 2, and water, wherein the etching composition includes about 11 wt % to about 16 wt % of water based on a total weight of the etching composition, and in an ¹H-NMR spectrum, a ratio of an area of a peak derived from Si—OR^{a} (wherein R^{a} is a substituted or unsubstituted alkyl group) to an area of a peak derived from Si—CH₃ is about 2 to about 16:

(R¹)ₐ(R²)_{b}(CH₃)Si—(OR³)_{(3-a-b)}, Chemical Formula 1
in Chemical Formula 1,
R¹ and R² may each independently be hydrogen, deuterium, or a substituted or unsubstituted C1 to C10 alkyl group,
R³ may be a substituted or unsubstituted C1 to C10 alkyl group,
a and b may each independently be an integer from 0 to 2, and 0≤a+b≤2;

(R⁵)_{c}(R⁶)ₐ(R⁷)Si—(OR⁸)_{(3-c-d)}, Chemical Formula 2
in Chemical Formula 2,
R⁵ and R⁶ may each independently be hydrogen, deuterium, a C1 to C10 alkyl group, a group in which at least one hydrogen of a C1 to C10 alkyl group is substituted with —NR^{c}R^{d}, or a group in which at least one —CH₂— of a C2 to C10 alkyl group is replaced by —NR^{e}—,
R⁷ may be a substituted or unsubstituted C1 to C10 alkyl group, wherein (i) one or more hydrogens of the alkyl group are substituted with —NR^{f}R^{g}, or (ii) the alkyl group is a C2 to C10 alkyl group in which at least one —CH₂— is a group replaced by —NR^{h}—,
R^{c} to R^{h} may each independently be hydrogen, a substituted or unsubstituted C1 to C5 alkyl group, a substituted or unsubstituted C3 to C10 cycloalkyl group, a substituted or unsubstituted C6 to C10 aryl group, or a (e.g., any suitable) combination thereof,
R⁸ may be a substituted or unsubstituted C1 to C10 alkyl group,
c and d may each independently be one of integers from 0 to 2, and 0≤c+d≤2.

The etching composition for a silicon nitride layer according to one or more embodiments includes a compound represented by Chemical Formula 1 and a compound represented by Chemical Formula 2, thereby increasing a ratio of the etch rate (etch selectivity) of the silicon nitride layer to the etch rate of the silicon oxide layer, and suppressing or reducing abnormal growth of the silicon oxide layer.

In one or more embodiments, the etching composition concurrently (e.g., simultaneously) satisfies the water content (e.g., amount) and the relative content (e.g., amount) of alkoxysilane relative to alkylsilane within a specific range, thereby suppressing or reducing a generation of bubbles due to friction between compounds and shortening a time (e.g., a duration) desired or required to heat the etching composition to an etching temperature.

In one or more embodiments, R¹ to R³ in Chemical Formula 1 may each independently be a substituted or unsubstituted C1 to C5 alkyl group. For example, in some embodiments, R¹ to R³ in Chemical Formula 1 may each independently be a substituted or unsubstituted methyl group, a substituted or unsubstituted ethyl group, or a substituted or unsubstituted propyl group, but embodiments of the present disclosure are not limited thereto.

In some embodiments, a sum of a and b in Chemical Formula 1 is 0 or 1, for example, 0, but embodiments of the present disclosure are not limited thereto.

In one or more embodiments, R⁵ to R⁷ of Chemical Formula 2 may each independently be a substituted or unsubstituted C1 to C10 alkyl group, wherein (i) one or more hydrogens of the alkyl group are substituted with —NR^{f}R^{g}, or (ii) the alkyl group is a C2 to C10 alkyl group in which at least one —CH₂— is a group replaced by —NR^{h}—, or may each independently be, for example, a substituted or unsubstituted C1 to C5 alkyl group, wherein (i) one or more hydrogens of the alkyl group are substituted with —NR^{f}R^{g}, or (ii) the alkyl group is a C2 to C5 alkyl group in which at least one —CH₂— is a group replaced by —NR^{h}—, but embodiments of the present disclosure are not limited thereto.

In one or more embodiments, R^{c} to R^{h} may each independently be hydrogen, a substituted or unsubstituted C1 to C5 alkyl group, a substituted or unsubstituted C6 to C10 aryl group, or a (e.g., any suitable) combination thereof, or, for example, hydrogen, a substituted or unsubstituted C1 to C5 alkyl group, or a (e.g., any suitable) combination thereof, but embodiments of the present disclosure are not limited thereto.

In one or more embodiments, a sum of c and d in Chemical Formula 2 is 0 or 1, for example, 0, but embodiments of the present disclosure are not limited thereto.

In one or more embodiments, in an ¹H-NMR spectrum, a ratio of an area of a peak derived from Si—OR^{a} (wherein R^{a} is a substituted or unsubstituted alkyl group) to an area of a peak derived from Si—CH₃ may be about 2 to about 16, for example about 3 to about 16, for example about 4 to about 16, for example about 4 to about 15, for example about 4 to about 14, for example about 4 to about 13, for example about 4 to about 12, for example about 4 to about 11, or for example about 4 to about 10, but embodiments of the present disclosure are not limited thereto. Within the range of the ratio of the area of the peak derived from Si—OR^{a} to the area of the peak derived from Si—CH₃, the generation of bubbles due to friction between compounds is suppressed or reduced and the time desired or required to heat the etching composition to the etching temperature is shortened.

In one or more embodiments, the water content (e.g., amount) (e.g., the amount of water) is about 11 wt % to about 16 wt %, for example about 11.5 wt % to about 15 wt %, for example about 12 wt % to about 15 wt %, for example about 12 wt % to about 14.5 wt %, for example about 12 wt % to about 14 wt %, for example about 12 wt % to about 13.8 wt %, for example about 12 wt % to about 13.5 wt %, or for example about 12 wt % to about 13 wt % based on the total weight of the etching composition, but embodiments of the present disclosure are not limited thereto. By including water in the etching composition within the above range, the generation of bubbles due to friction between compounds may be suppressed or reduced and the time desired or required to heat the etching composition to the etching temperature may be shortened.

The peak area ratio of the above-described 1H-NMR spectrum and the water content (e.g., amount) in the etching composition concurrently (e.g., simultaneously) satisfy the above ranges, so that the benefits of the etching composition according to one or more embodiments may be maximized or increased.

In one or more embodiments, a content (e.g., amount) of the compound represented by Chemical Formula 1 may be about 0.3 wt % to about 10 wt %, for example about 0.5 wt % to about 10 wt %, for example about 1 wt % to about 10 wt %, for example about 2 wt % to about 10 wt %, for example about 3 wt % to about 10 wt %, for example about 3 wt % to about 9 wt %, or for example about 3 wt % to about 8 wt % based on the total weight of the etching composition, but embodiments of the present disclosure are not limited thereto. By including the compound represented by Chemical Formula 1 in the etching composition within the above range, the etch selectivity may be improved or optimized.

In one or more embodiments, a content (e.g., amount) of the compound represented by Chemical Formula 2 may be about 0.5 wt % to about 30 wt %, for example about 0.5 wt % to about 25 wt %, for example about 0.5 wt % to about 20 wt %, for example about 1 wt % to about 30 wt %, for example about 1 wt % to about 25 wt %, for example about 1 wt % to about 20 wt %, or for example about 1 wt % to about 15 wt % based on the total weight of the etching composition, but embodiments of the present disclosure are not limited thereto. By including the compound represented by Chemical Formula 2 in the etching composition within the above range, etch selectivity may be improved or optimized while suppressing or reducing abnormal growth of the silicon oxide layer.

According to one or more embodiments, an etching method performed utilizing the etching composition for a silicon nitride layer is provided.

The etching method may include, for example, contacting the etching composition for a silicon nitride layer according to one or more embodiments with a substrate on which a silicon nitride layer is formed.

The method may further include removing the etching composition for a silicon nitride layer after the contacting.

The substrate on which the silicon nitride layer is formed may further include a silicon oxide layer.

For example, the substrate is not particularly limited as long as it is utilized in the art, and may be, for example, a semiconductor wafer.

The contacting of the etching composition for a silicon nitride layer with a substrate on which the silicon nitride layer is formed may include immersing the substrate on which the silicon nitride layer is formed in an etching bath including the etching composition for a silicon nitride layer, or spraying the etching composition for a silicon nitride layer on the substrate on which the silicon nitride layer is formed, but embodiments of the present disclosure are not limited thereto.

In some embodiments, heating the etching composition for a silicon nitride layer may be further included before contacting the etching composition for a silicon nitride layer with a substrate on which the silicon nitride layer is formed. The etching composition for a silicon nitride layer may be heated to a temperature of about 100° C. or higher, for example, about 100° C. to about 500° C. For example, in some embodiments, the etching composition for a silicon nitride layer may be heated to a temperature of about 150° C. to about 300° C., but embodiments of the present disclosure are not limited thereto.

By utilizing the etching composition for a silicon nitride layer according to one or more embodiments, the time taken to heat the etching composition to the above temperature in the operation of heating the etching composition may be shortened.

In one or more embodiments, the method may further include drying the substrate from which the silicon nitride layer has been removed after removing the etching composition for a silicon nitride layer.

The etching composition for a silicon nitride layer according to one or more embodiments may improve the etch selectivity of the silicon nitride layer relative to the silicon oxide layer if (e.g., when) utilizing the etching composition to etch a substrate including a silicon nitride layer and a silicon oxide layer, and prevent or reduce abnormal growth of silicon oxide.

Hereinafter, the present disclosure will be described in more detail through examples of the etching composition for a silicon nitride layer described above. However, the present disclosure is not technically limited by the following examples.

### Preparation of Etching Composition for Silicon Nitride Layer

### Examples 1 to 10

Methyltrimethoxysilane (alkoxysilane) and 3-aminopropyltriethoxysilane (aminosilane) were dissolved in deionized water (DIW), and the solution was treated under a reduced pressure to reduce an alkoxy concentration. Subsequently, phosphoric acid was mixed therewith to prepare an etching composition for a silicon nitride layer according to examples. Table 1 shows specific contents of the deionized water, the alkoxysilane, the aminosilane, and the phosphoric acid and also, a ratio of an area of a peak derived from Si—OR^{a} (wherein, R^{a} is a substituted or unsubstituted alkyl group) to that of a peak derived from Si—CH₃ in ¹H-NMR. The ¹H-NMR spectrum of the etching composition for silicon nitride layer according to Example 1 is shown in the drawing.

The measurement conditions for ¹H-NMR are as follows. The chemical shift of the peak derived from Si—CH₃ appears at 0.2 ppm, and the chemical shift of the peak derived from Si—OR^{a} appears at 3.8 ppm, 3.5 ppm, 3.4 ppm, 3.2 ppm, 0.9 ppm.

### <1H-NMR Measurement Conditions>

NMR device: AVANCE III 300 (Bruker)
Resonance frequency: 300 MHz
Accumulation: 16 times
Measurement solvent: CDCl₃
Chemical shift of reference substance and reference peak: TMS, 0 ppm
Sample concentration: [CDCl₃:sample=1:1]

### Comparative Examples 1 to 4

An etching composition of Comparative Example 1 was a phosphoric acid aqueous solution, and etching compositions of Comparative Examples 2 to 4 include phosphoric acid, alkoxysilane, aminosilane, and DIW in contents shown in Table 1.

TABLE 1

| | | | | | Peak |
|---|---|---|---|---|---|
| | Phosphoric acid | Alkoxysilane | Aminosilane | DIW | area ratio |
| | concentration | concentration | concentration | concentration | in ¹H-NMR |
| | (wt %) | (wt %) | (wt %) | (wt %) | spectrum |
| Comparative | 84.4 | — | — | 15.6 | 0 |
| Example 1 | | | | | |
| Comparative | 76.75 | 6.00 | 1.00 | 16.25 | 4.25 |
| Example 2 | | | | | |
| Comparative | 75.74 | 6.00 | 1.00 | 17.26 | 10.57 |
| Example 3 | | | | | |
| Comparative | 78.82 | 6.00 | 1.00 | 14.18 | 0.53 |
| Example 4 | | | | | |
| Example 1 | 80.75 | 6.00 | 1.00 | 12.25 | 2.08 |
| Example 2 | 79.71 | 6.00 | 1.00 | 13.29 | 8.22 |
| Example 3 | 78.82 | 6.00 | 1.00 | 14.18 | 9.69 |
| Example 4 | 78.33 | 6.00 | 1.00 | 14.67 | 9.13 |
| Example 5 | 78.63 | 6.00 | 1.00 | 14.37 | 7.45 |
| Example 6 | 80.48 | 6.00 | 1.00 | 12.52 | 2.70 |
| Example 7 | 79.88 | 6.00 | 1.00 | 13.12 | 3.96 |
| Example 8 | 79.24 | 6.00 | 1.00 | 13.76 | 3.83 |
| Example 9 | 78.69 | 6.00 | 1.00 | 14.31 | 3.01 |
| Example 10 | 78.34 | 6.00 | 1.00 | 14.66 | 9.92 |

### Evaluation 1: Evaluation of Bubble Volume Reduction

15 g of each of the etching composition of Comparative Examples 1 to 4 and Examples 1 to 10 was put in a 20 mL vial and shaken 40 times, and then placed on a floor (e.g., a board or platform) where a text was written to check the text. When the etching composition was shaken, bubbles were generated in the etching composition by physical friction, and then, a degree to which the bubbles remained over time, that is, a degree to which the text was visible, was observed to evaluate a degree to which the bubbles were removed. The results are shown in Table 2. In Table 2, “∘” indicates a case that the text was clearly distinguished due to no or small amounts of bubbles, “Δ” indicates a case that the text was partially distinguished due to some amounts of bubbles, and “X” indicates a case that the text was not distinguished due to a large amount of bubbles or freezing of a solution.

TABLE 2

| | 0 min | 1 min | 2 min | 3 min | 4 min | 5 min |
|---|---|---|---|---|---|---|
| Comparative Example 1 | ◯ | ◯ | ◯ | ◯ | ◯ | ◯ |
| Comparative Example 2 | X | X | X | X | X | Δ |
| Comparative Example 3 | X | X | X | X | X | X |
| Comparative Example 4 | X | X | X | X | X | X |
| Example 1 | ◯ | ◯ | ◯ | ◯ | ◯ | ◯ |
| Example 2 | Δ | Δ | Δ | ◯ | ◯ | ◯ |
| Example 3 | Δ | Δ | Δ | ◯ | ◯ | ◯ |
| Example 4 | X | Δ | Δ | ◯ | ◯ | ◯ |
| Example 5 | X | Δ | Δ | Δ | ◯ | ◯ |
| Example 6 | ◯ | ◯ | ◯ | ◯ | ◯ | ◯ |
| Example 7 | ◯ | ◯ | ◯ | ◯ | ◯ | ◯ |
| Example 8 | Δ | ◯ | ◯ | ◯ | ◯ | ◯ |
| Example 9 | Δ | Δ | ◯ | ◯ | ◯ | ◯ |
| Example 10 | X | X | Δ | ◯ | ◯ | ◯ |

Referring to Table 2, the etching compositions of Examples 1 to 9 each exhibited no bubbles or a small amount of bubbles, wherein if the bubbles were generated, the bubbles were reduced or disappeared within 1 minute. In contrast, the etching compositions of the comparative examples each exhibited a large amount of bubbles or crystallization. The composition of Comparative Example 4 exhibited agglomeration of silane compounds.

Evaluation 2: Etch rate, etch selectivity, and etch by-products Each of the etching compositions for a silicon nitride layer according to Examples 1 to 10 and Comparative Examples 1 to 4 was put in a beaker and heated to an etching temperature of 165° C., and then, a silicon nitride layer (LP-SiN layer) or a silicon oxide layer (PE-SiO layer) was added thereto and then etched at the etching temperature for 30 minutes. Before and after the etching, the LP-SiN layer or the PE-SiO layer was measured with respect to a thickness by utilizing an ellipsometer to obtain an etch rate. An etch rate (A) of the silicon nitride layer to an etch rate (B) of the silicon oxide layer was utilized to calculate an etch rate ratio (etch selectivity=A/B), and in addition, whether a byproduct after the etching was present or not was checked with naked eyes, and the results are shown in Table 3.

TABLE 3

| | Silicon | Silicon | | Presence |
|---|---|---|---|---|
| | nitride layer | oxide layer | | or absence |
| | etch rate | etch rate | Etch | of etch by- |
| | (Å/min) | (Å/min) | selectivity | products |
| Comparative | 78 | 3.0 | 26 | Presence |
| Example 1 | | | | |
| Comparative | 72 | 0.2 | 355 | Absence |
| Example 2 | | | | |
| Comparative | 73 | 0.2 | 365 | Absence |
| Example 3 | | | | |
| Comparative | 73 | 0.2 | 365 | Absence |
| Example 4 | | | | |
| Example 1 | 73 | 0.2 | 365 | Absence |
| Example 2 | 72 | 0.2 | 360 | Absence |
| Example 3 | 73 | 0.2 | 365 | Absence |
| Example 4 | 73 | 0.2 | 365 | Absence |
| Example 5 | 74 | 0.2 | 370 | Absence |
| Example 6 | 72 | 0.2 | 360 | Absence |
| Example 7 | 72 | 0.2 | 360 | Absence |
| Example 8 | 73 | 0.2 | 365 | Absence |
| Example 9 | 73 | 0.2 | 365 | Absence |
| Example 10 | 74 | 0.2 | 370 | Absence |

Referring to Table 3, each of the compositions of the examples exhibited excellent or suitable etch rate and etch selectivity and also, no byproduct after the etching process.

In the present disclosure, the term “comprise(s)/comprising”, “include(s)/including”, or “have (has)/having” are intended to designate that the performed characteristics, numbers, step, constituted elements, or a combination thereof is present, but it should be understood that the possibility of presence or addition of one or more other characteristics, numbers, steps, constituted element, or a combination are not to be precluded in advance.

As used herein, the singular forms “a,” “an,” and “the” are intended to include the plural forms as well, unless the context clearly indicates otherwise. Further, the utilization of “may” when describing embodiments of the present disclosure refers to “one or more embodiments of the present disclosure.” Expressions such as “at least one of,” “one of,” and “selected from,” when preceding a list of elements, modify the entire list of elements and do not modify the individual elements of the list. For example, “at least one of a, b, or c”, “at least one of a, b, and/or c”, “at least one selected from a, b, and c”, “at least one selected from among a to c”, etc. may indicate only a, only b, only c, both (e.g., simultaneously) a and b, both (e.g., simultaneously) a and c, both (e.g., simultaneously) b and c, all of a, b, and c, or variations thereof. Further, the “/” utilized herein may be interpreted as “and” or as “or” depending on the situation.

As used herein, the terms “substantially,” “about,” and similar terms are used as terms of approximation and not as terms of degree, and are intended to account for the inherent deviations in measured or calculated values that would be recognized by those of ordinary skill in the art. “About” or “approximately,” as used herein, is also inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

Hereinbefore, the certain embodiments of the present disclosure have been described and illustrated, however, it is apparent to a person with ordinary skill in the art that the present disclosure is not limited to the embodiment as described, and may be variously modified and transformed without departing from the spirit and scope of the present disclosure. Accordingly, the modified or transformed embodiments as such may not be understood separately from the technical ideas and aspects of the present disclosure, and the modified embodiments are within the scope of the claims of the present disclosure and equivalents thereof.

What is claimed is:

1. An etching composition comprising:
phosphoric acid;
a compound represented by Chemical Formula 1;
a compound represented by Chemical Formula 2; and
water,
wherein the etching composition comprises about 11 wt % to about 16 wt % of water based on a total weight of the etching composition, and
in an ¹H-NMR spectrum, a ratio of an area of a peak derived from Si—OR^{a} (wherein R^{a} is a substituted or unsubstituted alkyl group) to an area of a peak derived from Si—CH₃ is about 2 to about 16:
(R¹)ₐ(R²)_{b}(CH₃)Si—(OR³)_{(3-a-b)}, Chemical Formula 1
in Chemical Formula 1,
R¹ and R² being each independently hydrogen, deuterium, or a substituted or unsubstituted C1 to C10 alkyl group,
R³ being each independently a substituted or unsubstituted C1 to C10 alkyl group,
a and b being each independently an integer from 0 to 2, and 0≤a+b≤2; and
(R⁵)_{c}(R⁶)ₐ(R⁷)Si—(OR⁸)_{(3-c-d)}, Chemical Formula 2
in Chemical Formula 2,
R⁵ and R⁶ being each independently hydrogen, deuterium, a C1 to C10 alkyl group, a group in which at least one hydrogen of a C1 to C10 alkyl group is substituted with —NR^{c}R^{d}, or a group in which at least one —CH₂— of a C2 to C10 alkyl group is replaced by —NR^{e}—,
R⁷ being a substituted or unsubstituted C1 to C10 alkyl group, and (i) one or more hydrogens of the alkyl group being substituted with —NR^{f}R^{g}, or (ii) the alkyl group being a C2 to C10 alkyl group in which at least one —CH₂— is a group replaced by —NR^{h}—,
R^{c} to R^{h} being each independently hydrogen, a substituted or unsubstituted C1 to C5 alkyl group, a substituted or unsubstituted C3 to C10 cycloalkyl group, a substituted or unsubstituted C6 to C10 aryl group, or a combination thereof,
R⁸ being a substituted or unsubstituted C1 to C10 alkyl group,
c and d being each independently one of integers from 0 to 2, and 0≤c+d≤2, and
wherein the etching composition is for a silicon nitride layer.

2. The etching composition as claimed in claim 1, wherein, in Chemical Formula 1, R¹ to R³ are each independently a substituted or unsubstituted C1 to C5 alkyl group.

3. The etching composition as claimed in claim 1, wherein, in Chemical Formula 1, R³ is a methyl group, an ethyl group, or a propyl group.

4. The etching composition as claimed in claim 1, wherein, in Chemical Formula 1, a+b is 0.

5. The etching composition as claimed in claim 1, wherein, in Chemical Formula 2, R⁵ to R⁷ are each independently a substituted or unsubstituted C1 to C10 alkyl group,
and:
(i) one or more hydrogens of the alkyl group are substituted with —NR^{f}R^{g}; or
(ii) the alkyl group is a C2 to C10 alkyl group in which at least one —CH₂— is a group replaced by —NR^{h}—.

6. The etching composition as claimed in claim 5, wherein R^{c} to R^{h} are each independently hydrogen, a substituted or unsubstituted C1 to C5 alkyl group, or a combination thereof.

7. The etching composition as claimed in claim 1, wherein, in Chemical Formula 2, c+d is 0.

8. The etching composition as claimed in claim 1, wherein an amount of water is about 12 wt % to about 15 wt % based on the total weight of the etching composition.

9. The etching composition as claimed in claim 1, wherein the ratio of the area of the peak derived from Si—OR^{a} (wherein R^{a} is a substituted or unsubstituted alkyl group) to the area of the peak derived from Si—CH₃ is about 2 to about 10.

10. The etching composition as claimed in claim 1, wherein an amount of the compound represented by Chemical Formula 1 is about 0.3 wt % to about 10 wt % based on the total weight of the etching composition.

11. The etching composition as claimed in claim 1, wherein an amount of the compound represented by Chemical Formula 2 is about 0.5 wt % to about 30 wt % based on the total weight of the etching composition.

12. A method for etching a silicon nitride layer comprising:
contacting a surface of a silicon nitride layer with the etching composition as claimed in claim 1.

13. A silicon nitride layer comprising:
an etched surface etched by the etching composition as claimed in claim 1.
